(19) United States
(12) Patent Application Publication
(10) Pub. No.: US 2011/0133876 A1
(43) Pub. Date: Jun. 9, 2011

(54) Manufacture method for IC process with TOP and TOP-1 metal layers thickened and stacked inductor manufactured by this method

(76) Inventors: Tzuyin CHIU, Shanghai (CN); Xiangming XU, Shanghai (CN); Miao CAI, Shanghai (CN); Shengrong WANG, Shanghai (CN)

(21) Appl. No.: 12/960,065

(22) Filed: Dec. 3, 2010

(30) Foreign Application Priority Data
Dec. 8, 2009 (CN) 200910201908.8

(51) Int. Cl. H01F 5/00; H01L 21/02

(52) U.S. Cl. 336/200; 438/381; 257/E21.002

(57) ABSTRACT

A manufacture method for IC process with top and top-1 metal layers thickened and stacked inductor manufactured by this method is represented in this invention. This method includes: with multi metal layers, and the thickness of top and top-1 metal layers are more than 2.8 um. Thickened top and top-1 metal layers can reduce the resistance of top and top-1 metal layers, so can increase the Q factor of inductor.

The current invention claims a foreign priority to the China application number 200910201908.8 filed on Aug. 12, 2009.

### FIELD OF THE INVENTION

The invention is related to microelectronics, and more particularly related to manufacture method for IC process and the stacked inductor manufactured by this method

### BACKGROUND OF THE INVENTION

In present, there are a lot of passive devices in the integrated circuits. One of the most important components in RF CMOS/BiCMOS integrated circuits is on-chip inductor. Inductor has great impact on the RF characteristic in common wireless product. The design and analysis for this component has been widely studied. Nowadays, the high Q on-chip inductor has been widely used in voltage controlled oscillator, low noise amplifier and other RF building blocks. On-chip stacked inductor can reduce chip area in a large extent, which can reduce the production cost.

Q factor is the major specification of the inductor, high Q means low loss and high efficiency.

$$Q \approx \frac{wL}{{R}_{s}} \qquad Equation ( 1 )$$

Q is quality factor, w is frequency, L is inductance under a certain frequency, Rs is resistance under a certain frequency.

As shown in FIG. 1, in general RF IC process, in order to reduce the resistance of top metal to improve the Q factor of inductor, the thicken top metal (usually more than 2.8 um) is used. The metal layers beneath top metal is thin metal (usually less than 1 um) with a higher resistance than top thickened metal. In RFIC process, an inductor is usually formed with at least two metal layers, especially for stacked inductor. The relative higher resistance of metal layers beneath top metal has become the key factor to block the improvement of Q factor of inductor.

### SUMMARY OF THE INVENTION

This invention provides a manufacture method for IC process, and the Q factor of inductor manufactured by this method is much higher than that in conventional process with the same chip area.

Manufacture method for IC process with TOP and TOP-1 metal layers thickened includes: the structure with multi metal layers and the thickness of top and top-1 metal are more than 2.8 um.

The advantage of this invention is: with thickened top metal and top-1 metal, the Q factor is improved due to reduced metal resistance.

With this invention, a stacked inductor with multi metal layers includes the following key features: the thickness of top and top-1 metal is more than 2.8 um, and the metal coils of stacked inductor manufactured by this method are connected through via holes.

### BRIEF DESCRIPTION OF THE DRAWINGS

These and other features of this invention will be more readily understood from the following detailed description of the invention in conjunction with the accompanying drawings in which:

FIG. 1 is the cross-section diagram of conventional stacked inductor;

FIG. 2 is the cross-section diagram of stacked inductor in this invention;

FIG. 3 is the stereogram of stacked inductor in this invention;

### DETAILED DESCRIPTION OF THE INVENTION

In this invention, Manufacture method for IC process with TOP and TOP-1 metal layers thickened and stacked inductor manufactured by this method comprises: stacked top and bottom metal layers; the thicknesses of the top and the top-1 metal layers are more than 2.8 um, the ports of the inductor being disposed at end of metal coils; and the top and the bottom metal coils being connected through via holes.

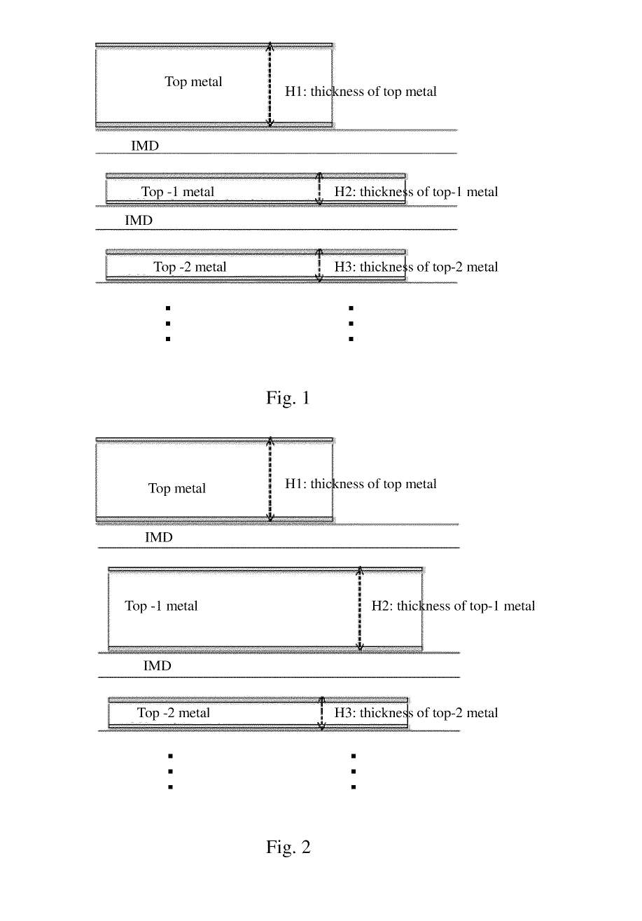

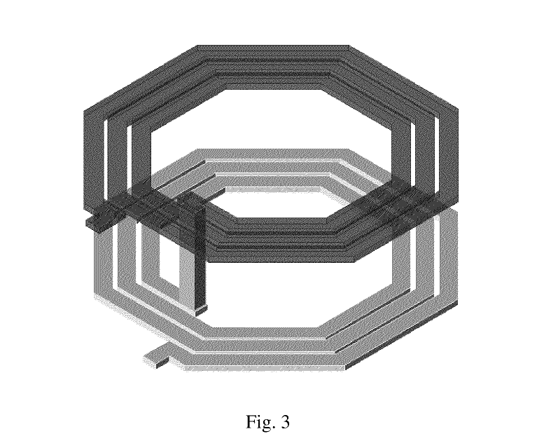

More detailed, the layout of stacked inductor formed by thicker top and top-1 metal is shown as FIG. 2 (taking two layers and octagonal stacked inductor for example), and FIG. 3. From FIG. 3, the thickness of top and top-1 metal coil is equal and both more than 2.8 um; the widths of both top and top-1 metal coils which are aligned with each other are equal. The inductor starting from an inductance port, a first layer of the metal coil, after winding into the most inner end, being connected through a via hole between layers to another layer of the metal coil, which further winds helically to the most outer end.

The structure of this invention (shown in FIG. 2), the top and top-1 layers are both thicker metal (usually thicker than 2.8 um), with this invention, the resistance of top two metal layers are reduced, and a higher Q factor stacked inductor will be realized. Through this method, a stacked inductor with high inductance and relative high Q factor is available, which will save the chip area enormously.

Take a stacked inductor with 2 turns as example, with the same chip area, the inductor formed by this method, the inductance and Q factor are L=2.3 nH, Q=8.6, while same inductor formed by general IC process with only thicker top metal, L and Q are L=2.3 nH, Q=4.8. The Q factor improved enormously.

In the FIG. 3, the metal width and thickness of top and top-1 keeps equal, and these two layers of metal coil are aligned with each other. With this structure, the mutual inductance between top and down metal can efficiently enhanced, and thickened top-1 metal can reduce the resistance to improve the Q factor. It is not needed to keep the width of two metal layers equal.

The new method of this invention can be applied to single ended, differential or other type inductor structures. The spiral direction could be clockwise or reverse. The layout of metal coil can be rectangle, octagon, circle or other styles.

The new structure of this invention is not limited to two metal layers. This invention is preferentially applied to the top metal layer and top minus one layer. However, other layers are also suitable for use.

While the invention has been particularly shown and described with reference to the preferred embodiments thereof, it will be understood by those skilled in the art that various changes in form and details may be made without departing from the spirit of the invention or from the scope of the appended claims.

1. A manufacture method for IC process with top and top-1 metal layers thickened comprises:
manufacturing multi metal layers including a top and a top-1 metals;
the thickness of the top and the top-1 metal is more than 2.8 um.

2. A stacked inductor formed by the manufacture method of claim 1 with multi metal layers comprising a top and a top-1 metal layers, comprising:
stacked top and bottom metal layers;
the thicknesses of the top and the top-1 metal layers are more than 2.8 um;
ports of the inductor being disposed at end of metal coils;
top and bottom metal coils being connected through via holes.

3. The stacked inductor according to claim 2 manufactured by the integrated circuit manufacturing method with the top and the top-1 metal layers thickened, characterized in that: with the inductor starting from an inductance port, a first layer of the metal coil, after winding into the most inner end, being connected through a via hole between layers to another layer of the metal coil, which further winds helically to the most outer end.

4. The stacked inductor claim 2 manufactured by the integrated circuit manufacturing method with the top and the top-1 metal layers thickened, comprises: the width of each of the metal coils of the stacked inductor varies.

5. The stacked inductor of claim 2 manufactured by the integrated circuit manufacturing method with the top and the top-1 metal layers thickened, comprises: a shape of the stacked inductor is selected from the group consisting of octagon, rectangle or circle.

6. The stacked inductor of claim 2 manufactured by the integrated circuit manufacturing method with the top and the top-1 metal layers thickened, comprises: the metal coils being wound in clockwise or counterclockwise direction.
